(19) United States
(12) Patent Application Publication
(10) Pub. No.: US 2003/0122552 A1
(43) Pub. Date: Jul. 3, 2003

(54) Signal quality indicator on a powerline-modem

(76) Inventor: Louis Robert Litwin, Plainsboro, NJ (US)

Correspondence Address: JOSEPH S. TRIPOLI, THOMSON MULTIMEDIA LICENSING INC., 2 INDEPENDENCE WAY, P.O. BOX 5312, PRINCETON, NJ, 08543-5312, US

(21) Appl. No.: 10/033,314

(22) Filed: Dec. 28, 2001

(51) Int. Cl. G01R 29/26

(52) U.S. Cl. 324/614

(57) ABSTRACT

An apparatus for determining signal quality on an outlet of a powerline network includes a powerline modem connected to a power outlet of a powerline network for sending and receiving a signal across the powerline network, and a signal quality indicator coupled to said powerline modem network for indicating signal quality received from another powerline modem coupled to the powerline network.

### BACKGROUND

1. Technical Field

This disclosure relates to power-line modem networks, and more particularly, to a signal quality indicator on a Powerline modem for the purpose of aiding the user with device placement on the network.

2. Description of the Related Art

Powerline modems communicate by employing a power network as a transmission medium. Since modems in a plurality of locations share the power network, the shared powerline is a medium that permits a powerline modem in one house to “see” the powerline modems (and their data) at other locations, for example, other homes. Since the powerline is shared and is common to all homes data can be accessed freely over the powerline.

The powerline modem network is a harsh network environment for operating powerline modems due to a number of different impairments, such as noise, reflections, and transients from motors switching. Because of this harsh network environment, signal quality for powerline modems can vary greatly depending on which outlet in the home or office network the modem is plugged into.

Accordingly, there is a need to include a signal quality indicator on the powerline modem itself in order to aid the network user in finding an appropriate outlet in the network for connecting with the powerline modem.

### SUMMARY OF THE INVENTION

The present apparatus for determining signal quality on an outlet of a powerline network includes a powerline modem connectable to a power outlet of a powerline network for sending and receiving a signal across the powerline network; and

a signal quality indicator coupled to the powerline modem network for indicating signal quality received from another powerline modem coupled to the powerline network.

In an alternative embodiment of the present invention, a method for determining signal quality on an outlet of a powerline network includes the steps of: sending a signal across said powerline network; receiving a signal across said powerline network; sensing signal quality received from said powerline network; and indicating signal quality received from said powerline network.

### BRIEF DESCRIPTION OF DRAWINGS

This disclosure will present in detail the following description of preferred embodiments with reference to the following figures wherein:

FIG. 1 is a block diagram showing a powerline modem with a signal quality indicator connected to a power outlet of a powerline network in accordance with the present invention;

FIG. 2 is a block diagram showing an exemplary powerline; and

FIG. 3 is a block diagram of an exemplary application of the inventive powerline modem with signal quality indicator.

### DETAILED DESCRIPTION OF PREFERRED EMBODIMENTS

Large variations in powerline modem signal quality occur depending on the outlet location used. Difficulty can arise in finding an outlet suitable for connection with a powerline modem. These difficulties can arise when the powerline modem is connected to a computer. In that case the user would have to go to each outlet, get the modems and computers up and running, and check the signal thru put at each outlet location. Such a procedure can be time consuming and inefficient. If the powerline modem is in a standalone device, such as an Internet radio, the devoice would have to be turned on and the user would have to try and judge signal quality based on audio quality. This method of determining signal quality is difficult to determine. If the powerline modem is in a standalone device that does not have an output that relates to signal quality, such as a powerline modem connected a printer, the user cannot properly judge connection quality. The inventive powerline modem with signal quality indicator provides a quick and easy way for the user to determine what outlets on the powerline network are proper for connection with the powerline modem and equipment connected to the powerline network through the powerline modem. Known solutions employ trial and error techniques requiring the devices connected to the powerline modem to be turned on, and up and running in order to judge the quality at different outlets.

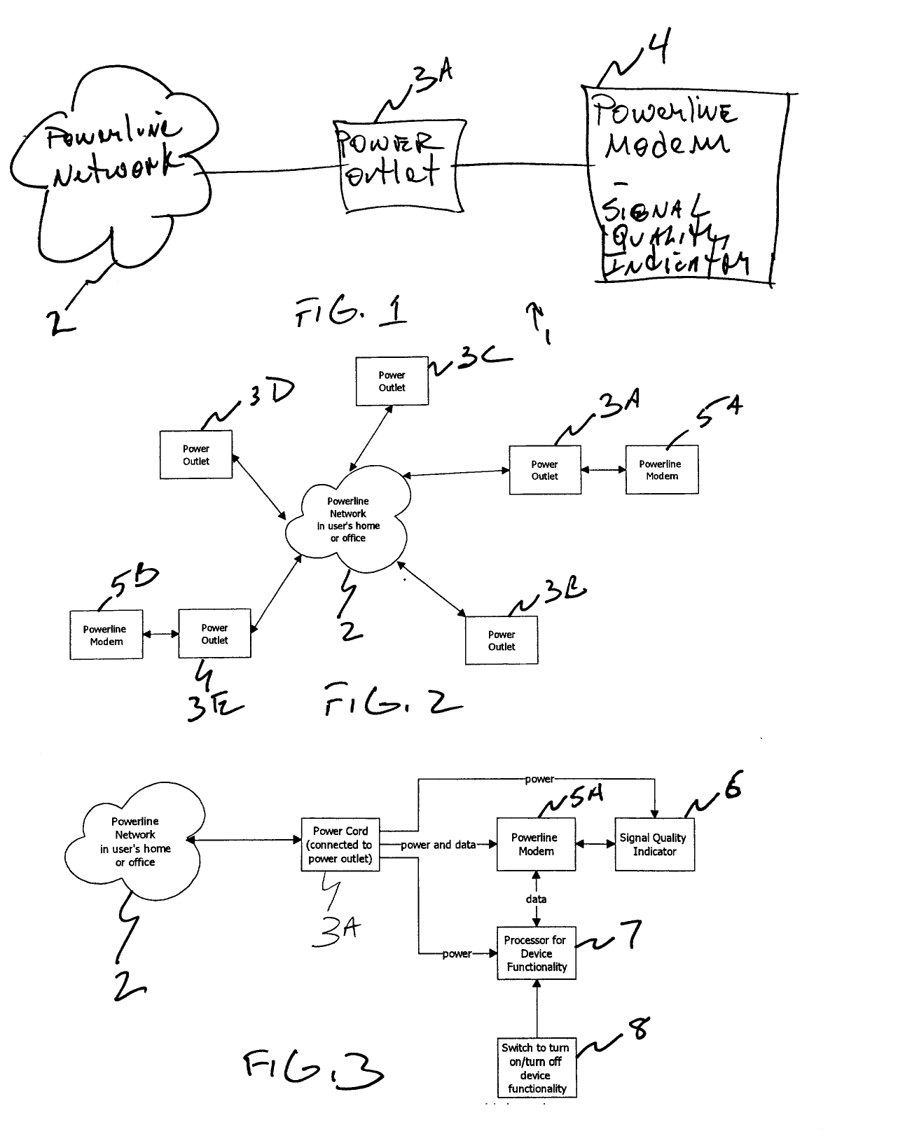

Referring now in specific detail to the drawings in which like reference numerals identify similar or identical elements throughout the several views, and initially to FIG. 1, a block diagram 1 showing a powerline modem 4 with a signal quality indicator connected to a power outlet 3A of a powerline network 2. Preferably the powerline modem will have a display for indicating powerline modem signal quality. An exemplary display would be a light emitting diode (LED) display in which bars lit is based on signal quality. The capability to measure and indicate signal quality is separate and does not rely on the functionality of a device connected to the powerline network 2 through the powerline modem 4. The signal quality indicator preferably turns on automatically as soon as the powerline modem is connected to a power outlet 3A. In this manner, a device connected to the powerline modem does not need to be turned on and operational in order to measure signal quality.

Referring now to FIG. 2, an exemplary powerline modem network for home or office use is shown. The powerline network 2 is connectable through power outlets 3A through 3E. Exemplary powerline modems 5A and 5B are shown connected to power outlets 3A and 3E.

At least two powerline modems must be plugged in to the network in order to constitute a network. The indicator on a given powerline modem can indicate the signal quality received from other devices on the network.

Referring now to FIG. 3, there is shown a block diagram of an exemplary embodiment of the inventive powerline modem with signal quality indicator. The processor 7 for determining functionality of a device coupled to the powerline modem is shown as a completely separate block from the signal quality indicator circuit 6. An optional manual on/off switch 8 is shown, but is not necessary to practice the invention. For example, if a device connected through the powerline modem is an internet radio, that internet radio does not have to be turned on and playing music in order for the signal quality indicator to properly function. Merely plugging the powerline modem and associated blocks 6 and 7 into the power outlet 3A can power the powerline modem and blocks 6 and 7. In contrast, determining functionality of a device connected to the powerline modem would typically require turning on that device. The inventive powerline modem with signal quality indicator can allow a user to quickly measure signal strength at different outlets by merely plugging the powerline modem, without powering up the device for connection to the network through the powerline modem.

Signal quality can be based can be based on any known metrics technique. If the powerline modem uses multiple carriers, proper signal quality be based on the number of carriers received from another transmitting powerline modem. Estimates of signal-to-noise ratio received from another transmitting device can be used, as well as bit error rate BER for training sequences. Any other number of metrics can be used.

What is claimed is:

1. An apparatus for determining signal quality on an outlet of a powerline network, comprising:
a powerline modem connectable to a power outlet of a powerline network for sending and receiving a signal across said powerline network; and
a signal quality indicator coupled to said powerline modem network for indicating signal quality received from another powerline modem coupled to said powerline network.

2. The apparatus as recited in claim 1, wherein said signal quality indicator and said powerline modem are an integral unit.

3. The apparatus as recited in claim 1, wherein said signal quality is based on a metric.

4. The apparatus as recited in claim 3, wherein said metric in a case where said powerline modem uses multiple carries is based on the number of carriers received from another powerline modem coupled to said network.

5. The apparatus as recited in claim 3, wherein said metric is based on signal-to-noise ratio SNR of a signal received from another powerline modem coupled to said network.

6. The apparatus as recited in claim 5, wherein said metric is based on a bit error rate sequence received from another powerline modem coupled to said network.

7. The apparatus as recited in claim 1, further comprising an on/off switch for coupling power to said apparatus from an outlet of said powerline network.

8. The apparatus as recited in claim 1, wherein said powerline modem and said signal quality indicator are each connectable to an outlet on said powerline network.

9. A method for determining signal quality on an outlet of a powerline network, comprising the steps of:
sending a signal across said powerline network;
receiving a signal across said powerline network;
sensing signal quality received from said powerline network; and
indicating signal quality received from said powerline network.

10. The method as recited in claim 9, wherein said steps of sending and receiving are by a powerline modem coupled to said powerline network.

11. The method as recited in claim 9, wherein said steps of sensing and indicating are by a signal quality indicator coupled to said powerline network.

12. The method as recited in claim 9, wherein said indicating step comprises a metric based on the number of carriers received from another powerline modem coupled to said powerline network.

13. The method as recited in claim 9, wherein said indicating step comprises a metric based on the signal-to-noise ratio of a signal received from another powerline modem coupled to said network.

14. The method as recited in claim 9 wherein said metric is based on a bit error rate sequence received from another powerline modem coupled to said powerline network.
